(19) United States
(12) Patent Application Publication
(10) Pub. No.: US 2026/0060141 A1
(43) Pub. Date: Feb. 26, 2026

(54) SEMICONDUCTOR PACKAGE STRUCTURE AND MANUFACTURING METHOD THEREOF

(71) Applicant: Powertech Technology Inc., Hsinchu County (TW)

(72) Inventors: Shang-Yu Chang Chien, Hsinchu County (TW); Chih Hao Chen, Hsinchu County (TW); Yi-Kai Fu, Hsinchu County (TW)

(73) Assignee: Powertech Technology Inc., Hsinchu County (TW)

(21) Appl. No.: 19/031,122

(22) Filed: Jan. 17, 2025

(30) Foreign Application Priority Data
Aug. 22, 2024 (TW) 113131644

(51) Int. Cl. H01L 23/00; H01L 23/498; H01L 25/00; H01L 25/11

(52) U.S. Cl. CPC H01L 24/24; H01L 24/19; H01L 24/25; H01L 25/117; H01L 25/50; H01L 23/49811; H01L 2224/19; H01L 2224/24146; H01L 2224/244; H01L 2224/2518

(57) ABSTRACT

A semiconductor package structure includes a first package and a second package. The first package includes a first redistribution layer, a second redistribution layer, a third redistribution layer, at least one first chip, at least one second chip, multiple first conductive elements, multiple second conductive elements, a first encapsulant, a second encapsulant, and multiple solders. The second redistribution layer is located between the first redistribution layer and the third redistribution layer and includes multiple chip connectors. Each chip connector includes a connecting pad, a nickel layer, and a gold layer. The connecting pad has top surface and a peripheral surface. The nickel layer covers the top surface and the peripheral surface of the connecting pad, and the gold layer covers the nickel layer located on the top surface of the connecting pad. The second encapsulant is disposed on the third redistribution layer and is electrically connected to the first encapsulant.

### CROSS-REFERENCE TO RELATED APPLICATION

This application claims the priority benefit of Taiwan application serial no. 113131644, filed on Aug. 22, 2024. The entirety of the above-mentioned patent application is hereby incorporated by reference herein and made a part of this specification.

### BACKGROUND

Technical Field The disclosure relates to a package structure and a manufacturing method thereof, and in particular to a semiconductor package structure and a manufacturing method thereof.

### Description of Related Art

As technology in the semiconductor industry continues to evolve, end products are becoming lighter and lighter, including laptops, smartphones, and wearable devices. In order to increase the density of components per unit volume, stacking technology plays a very important role not only at the wafer level but also at the packaging level. This means that multiple chips in a package need to be highly integrated into one system, so the space between the chips is reduced. Currently, flip chip bonding is a very efficient method to shorten signal transmission distance. However, with the geometrical structure of the existing flip chip pad, the nickel layer and the gold layer are sequentially stacked on the copper pad, and the edges of the nickel layer and the gold layer are flush with the edge of the copper pad, which cause the solder to collapse along the side wall of the flip chip pad after flip chip bonding, and also cause the copper pad to be laterally eroded, thereby affecting bonding reliability.

### SUMMARY

The disclosure provides a semiconductor package structure, which can limit an interacting region between a solder and a chip connector, while preventing the connecting pad from being laterally eroded to have improved structural reliability.

The disclosure also provides a manufacturing method of a semiconductor package structure, which is used to manufacture the semiconductor package structure.

A semiconductor package structure of the disclosure includes a first package and a second package. The first package includes a first redistribution layer, a second redistribution layer, a third redistribution layer, at least one first chip, at least one second chip, multiple first conductive elements, multiple second conductive elements, a first encapsulant, a second encapsulant, and multiple solders. The second redistribution layer is located between the first redistribution layer and the third redistribution layer. The second redistribution layer has a first side and a second side opposite to each other and includes multiple chip connectors located on the second side. Each chip connector includes a connecting pad, a nickel layer, and a gold layer. The connecting pad has a top surface and a peripheral surface connected to the top surface. The nickel layer covers the top surface and the peripheral surface of the connecting pad, and the gold layer covers the nickel layer located on the top surface of the connecting pad. The at least one first chip is disposed on the first redistribution layer and is electrically connected to the first side of the second redistribution layer. The at least one second chip is disposed on the chip connectors through the solders and is electrically connected to the second side of the second redistribution layer. The first conductive elements are electrically connected to the first redistribution layer and the second redistribution layer. The second conductive elements are electrically connected to the second redistribution layer and the third redistribution layer. The first encapsulant encapsulates the at least one first chip and the first conductive elements. The second encapsulant encapsulates the at least one second chip and the second conductive elements. The second package is disposed on the third redistribution layer of the first package and is electrically connected to the first package.

In an embodiment of the disclosure, the semiconductor package structure further includes multiple third conductive elements and multiple fourth conductive elements. The third conductive elements are disposed on at least one first active surface of the at least one first chip. The at least one first chip is electrically connected to the second redistribution layer through the third conductive elements. The fourth conductive elements are disposed on at least one second active surface of the at least one second chip. The solders are respectively located between the fourth conductive elements and the chip connectors.

In an embodiment of the disclosure, the first conductive elements are disposed on the first redistribution layer and are connected to the first side of the second redistribution layer. The at least one first chip is located between the first conductive elements. The first encapsulant has an upper surface and a lower surface opposite each other. The upper surface covers the first side of the second redistribution layer, and the lower surface covers the first redistribution layer.

In an embodiment of the disclosure, the second conductive elements are disposed on the second side of the second redistribution layer and are connected to the third redistribution layer. The at least one second chip is located between the second conductive elements. The second encapsulant has an upper surface and a lower surface opposite each other. The upper surface covers the third redistribution layer, and the lower surface covers the second side of the second redistribution layer.

In an embodiment of the disclosure, an orthographic projection of each first conductive element on the second redistribution layer is aligned or misaligned with an orthographic projection of each second conductive element on the second redistribution layer.

In an embodiment of the disclosure, the semiconductor package structure further includes multiple solder balls disposed on the first package and located on a surface of the first redistribution layer away from the at least one first chip. The solder balls are electrically connected to the first redistribution layer of the first package.

In an embodiment of the disclosure, the second package includes a substrate, at least one third chip, and a third encapsulant. The at least one third chip is disposed on the substrate and is electrically connected to the substrate. The third encapsulant seals the at least one third chip. The substrate is located between the at least one third chip and the first package.

In an embodiment of the disclosure, the semiconductor package structure further includes multiple connectors disposed between the first package and the second package. The second package is electrically connected to the first package through the connectors.

In an embodiment of the disclosure, the semiconductor package structure further includes an underfill filled between the first package and the second package and encapsulating the connectors.

In an embodiment of the disclosure, the semiconductor package structure further includes an underfill filled between the at least one second chip and the second side of the second redistribution layer and encapsulating the solders and the chip connectors.

In an embodiment of the disclosure, the semiconductor package structure further includes an adhesion layer disposed on the first redistribution layer. The at least one first chip is fixed on the first redistribution layer through the adhesion layer.

In an embodiment of the disclosure, an orthographic projection of the at least one second chip on the second redistribution layer overlaps with an orthographic projection of the at least one first chip on the second redistribution layer.

In an embodiment of the disclosure, a first peripheral edge of the first package protrudes a spacing relative to a second peripheral edge of the second package.

In an embodiment of the disclosure, the first redistribution layer, the second redistribution layer, and the third redistribution layer respectively include a fan-out redistribution layer.

In an embodiment of the disclosure, a first peripheral edge of the gold layer of each chip connector is aligned with a second peripheral edge of the nickel layer, and the peripheral surface of the connecting pad is retracted relative to the first peripheral edge.

A manufacturing method of a semiconductor package structure of the disclosure includes the following steps. A carrier plate and a first redistribution layer formed on the carrier plate are provided. Multiple first conductive elements are formed on the first redistribution layer and are electrically connected to the first redistribution layer. At least one first chip is disposed on the first redistribution layer. A first encapsulant is formed on the first redistribution layer. The first encapsulant encapsulates the at least one first chip and the first conductive elements and exposes a first surface of each first conductive element. A second redistribution layer is formed on the first surface and the first encapsulant of each first conductive element. The second redistribution layer has a first side and a second side opposite each other. The at least one first chip and the first conductive elements are electrically connected to the first side of the second redistribution layer. Multiple chip connectors are formed on the second side of the second redistribution layer. Each chip connector includes a connecting pad, a nickel layer, and a gold layer. The connecting pad has a top surface and a peripheral surface connected to the top surface. The nickel layer covers the top surface and the peripheral surface of the connecting pad, and the gold layer covers the nickel layer located on the top surface of the connecting pad. Multiple second conductive elements are formed on the second side of the second redistribution layer and are electrically connected to the second redistribution layer. Multiple solders are formed on the at least one second chip. The at least one second chip is disposed on the chip connectors through the solders and is electrically connected to the second side of the second redistribution layer. A second encapsulant is formed on the second redistribution layer. The second encapsulant encapsulates the at least one second chip and the second conductive elements and exposes a second surface of each second conductive element. A third redistribution layer is formed on the second surface of each second conductive element and the second encapsulant. The third redistribution layer is electrically connected to the second conductive elements. The carrier plate is removed to expose the first redistribution layer. The first redistribution layer, the second redistribution layer, the third redistribution layer, the at least one first chip, the at least one second chip, the first conductive elements, the second conductive elements, the first encapsulant, the second encapsulant, and the solders define a first package. At least one second package is disposed on the third redistribution layer of the first package and is electrically connected to the first package.

In an embodiment of the disclosure, the step of forming the chip connectors on the second side of the second redistribution layer includes the following steps. A seed layer is formed on the second side of the second redistribution layer. A patterned photoresist layer is formed on the seed layer. The patterned photoresist layer has multiple first openings, and the first openings respectively expose a first part of the seed layer. Each connecting pad is electroplated on the first part of the seed layer exposed by each first opening using the patterned photoresist layer as an electroplating mask. Each first opening exposes the top surface of each connecting pad. A part of the patterned photoresist layer located around each connecting pad is removed to form a photoresist layer having multiple second openings. Each second opening exposes the top surface and the peripheral surface of each connecting pad and a second part of the seed layer. The nickel layer is electroplated on the top surface and the peripheral surface of each connecting pad and the second part of the seed layer exposed by each second opening using the photoresist layer as an electroplating mask. The gold layer is electroplated on the nickel layer using the photoresist layer as an electroplating mask. The photoresist layer and the seed layer below the photoresist layer are removed.

In an embodiment of the disclosure, the step of forming the second conductive elements on the second side of the second redistribution layer includes the following step. The second conductive elements are electroplated on a third part of the seed layer when removing the photoresist layer to expose the seed layer below the photoresist layer.

In an embodiment of the disclosure, a method of removing the part of the patterned photoresist layer located around each connecting pad includes an exposure procedure and a development procedure, an over development procedure, or a plasma dry etching procedure.

In an embodiment of the disclosure, a singulation procedure is executed after disposing the at least one second package on the third redistribution layer of the first package.

Based on the above, in the semiconductor package structure of the disclosure, the chip connector includes the connecting pad, the nickel layer, and the gold layer. The nickel layer covers the top surface and the peripheral surface of the connecting pad, and the gold layer covers the nickel layer located on the top surface of the connecting pad. Through the geometrical structure design of the chip connector, the interacting region between the solder and the gold layer may be limited to prevent the solder from collapsing along the peripheral surface of the connecting pad, and the nickel layer encapsulating the peripheral surface of the connecting pad may prevent the peripheral surface of the connecting pad from being laterally eroded, thereby achieving improved structural reliability.

In order for the features and advantages of the disclosure to be more comprehensible, the following specific embodiments are described in detail in conjunction with the drawings.

### BRIEF DESCRIPTION OF THE DRAWINGS

FIG. 1A to FIG. 1N are schematic cross-sectional views of a manufacturing method of a semiconductor package structure according to an embodiment of the disclosure.

### DESCRIPTION OF THE EMBODIMENTS

The embodiments of the disclosure may be understood together with the drawings, and the drawings of the disclosure are also regarded as a part of the description of the disclosure. It is to be understood that the drawings of the disclosure are not drawn to scale and, in fact, the dimensions of components may be arbitrarily enlarged or reduced to clearly illustrate the features of the disclosure.

Unless expressly stated otherwise, directional terms (for example, upper, lower, left, right, front, back, top, bottom) used herein are used only with reference to the drawings and are not intended to imply absolute orientation. Furthermore, unless expressly stated otherwise, steps of any method described herein is in no way intended to be construed as being required to be executed in a particular order.

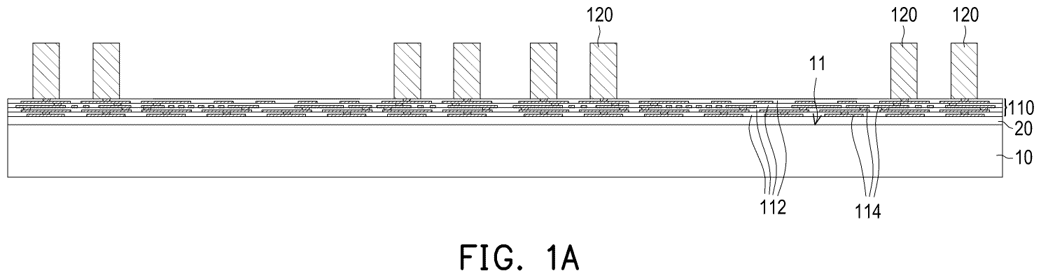

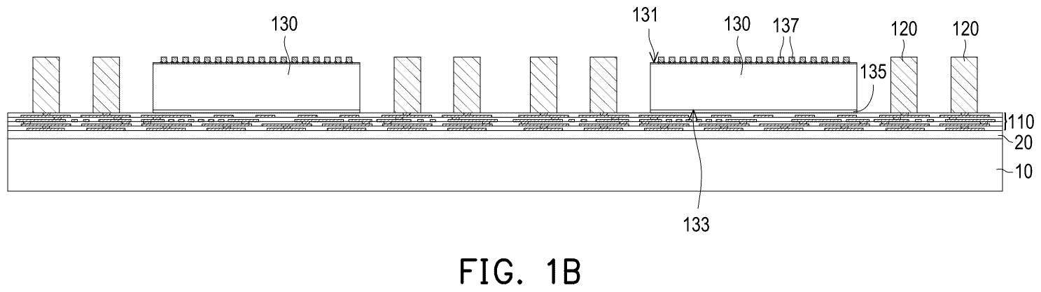

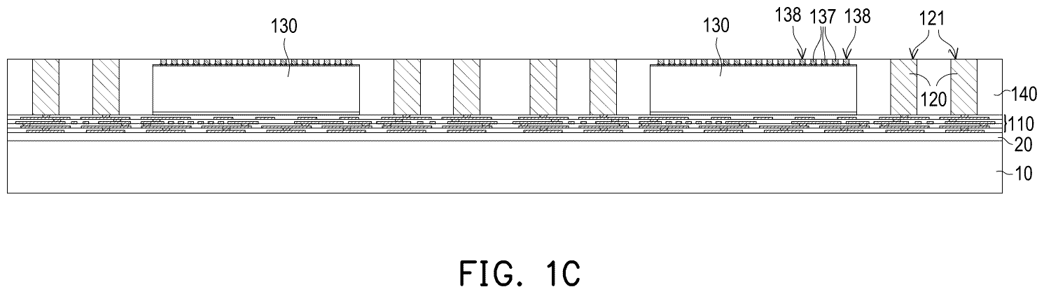

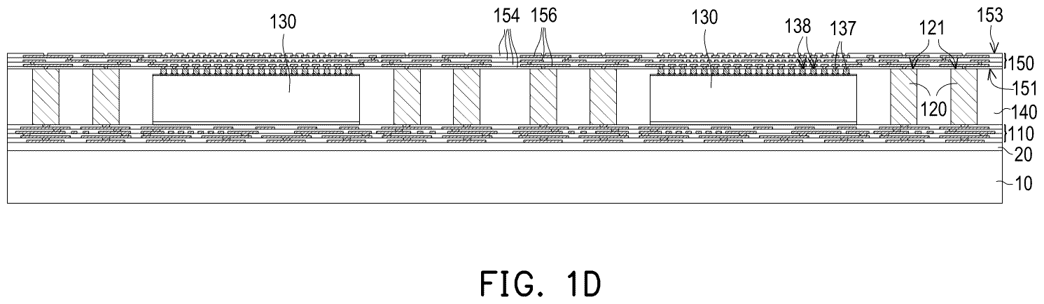

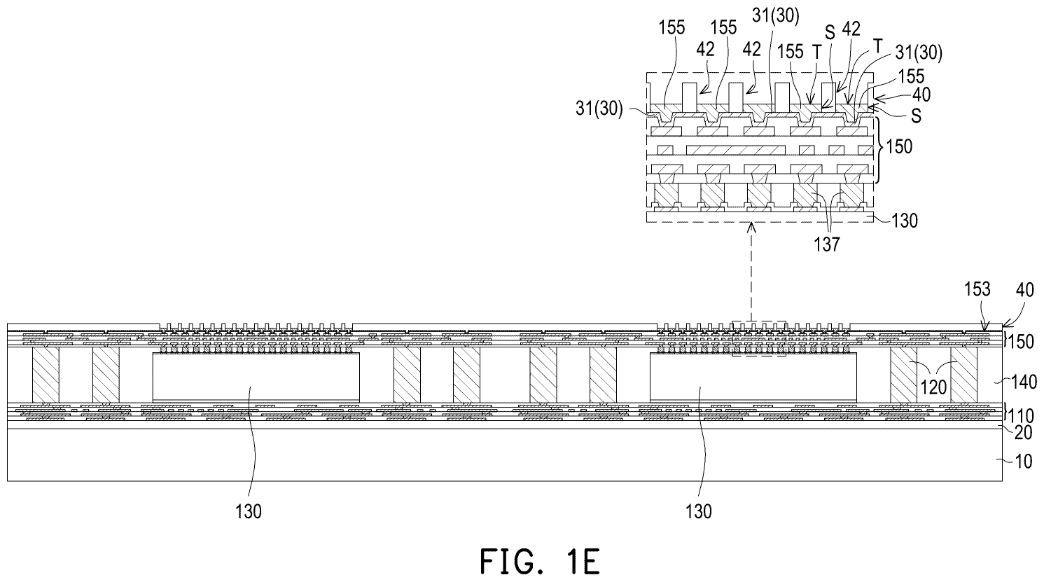

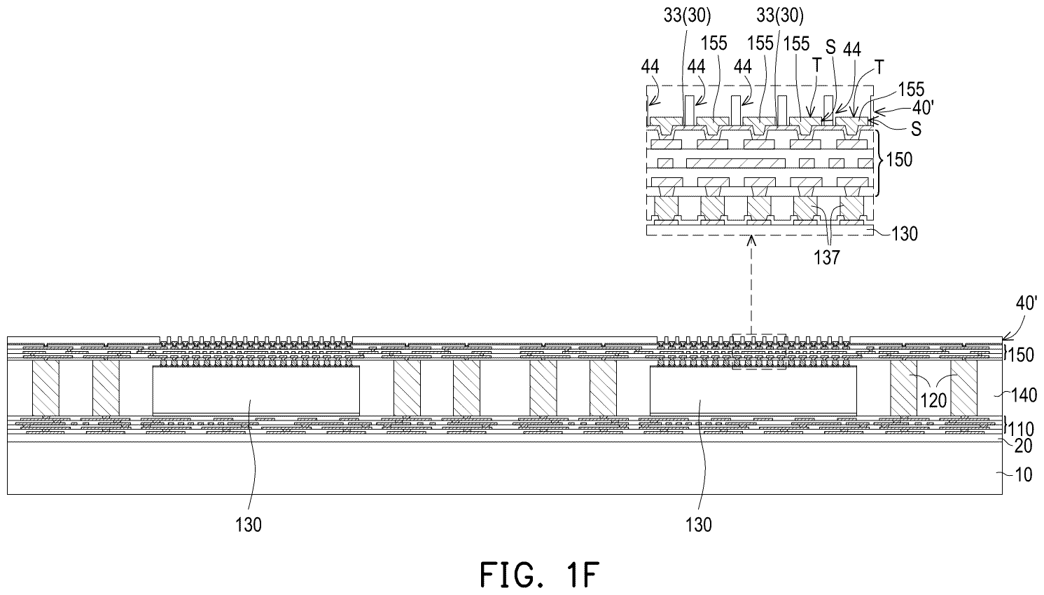

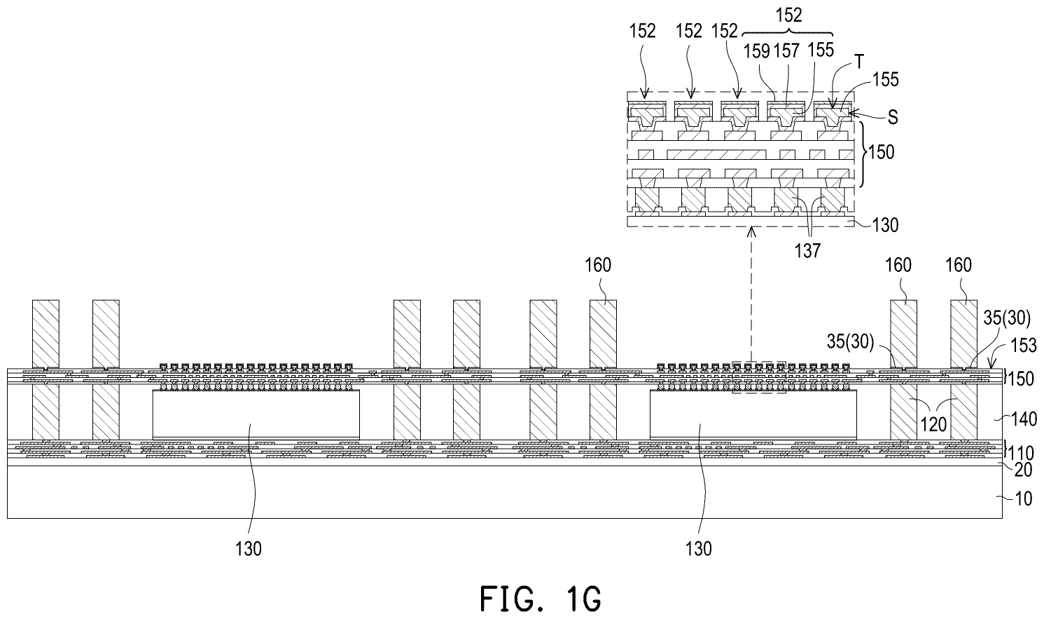

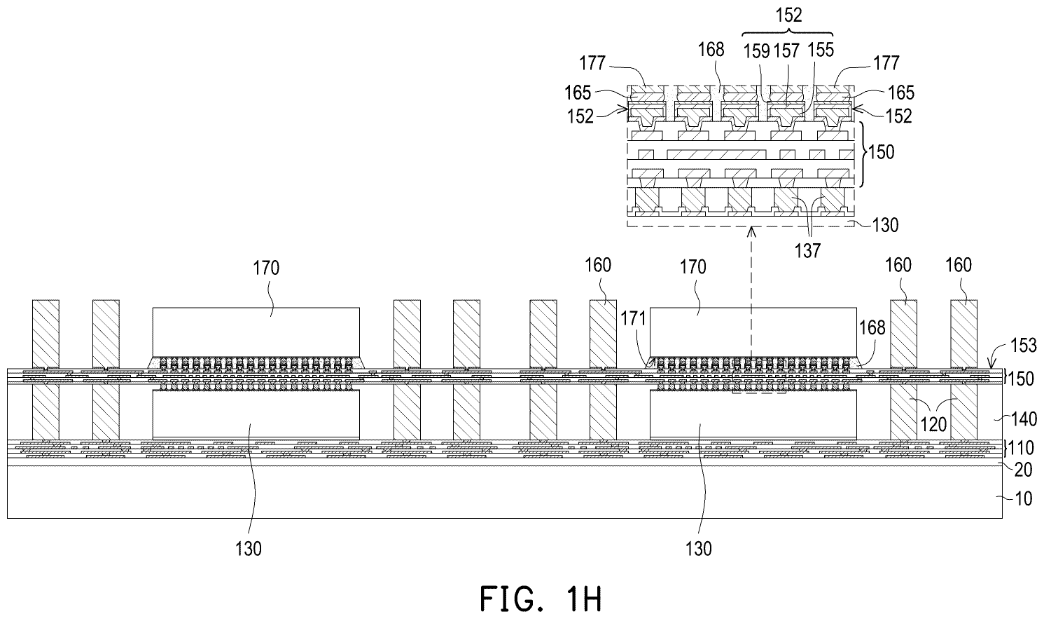

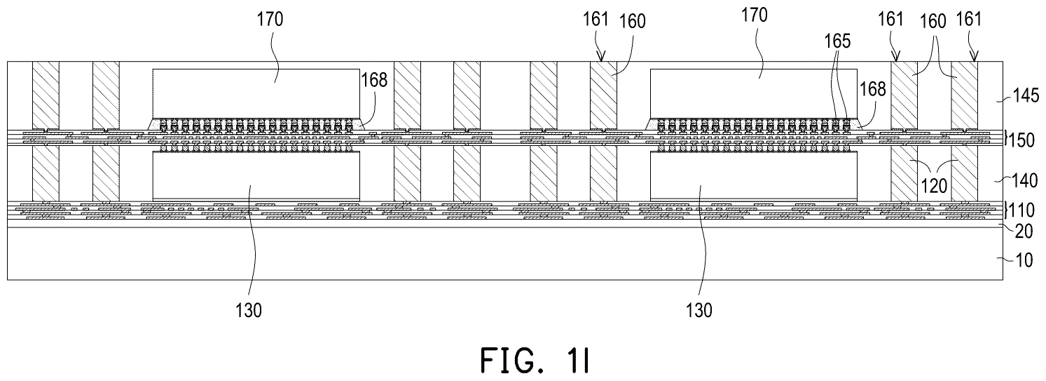

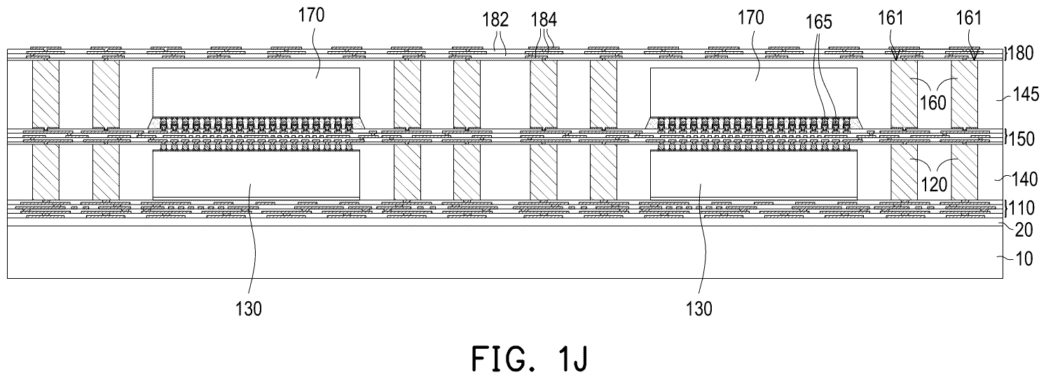

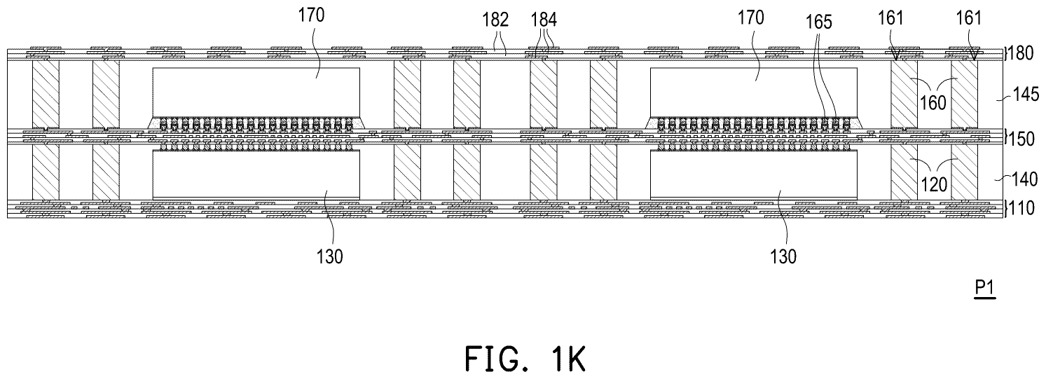

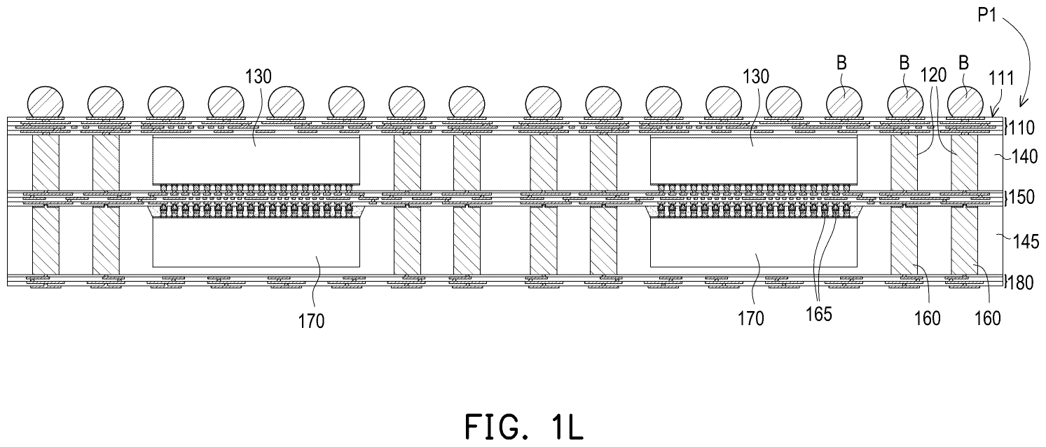

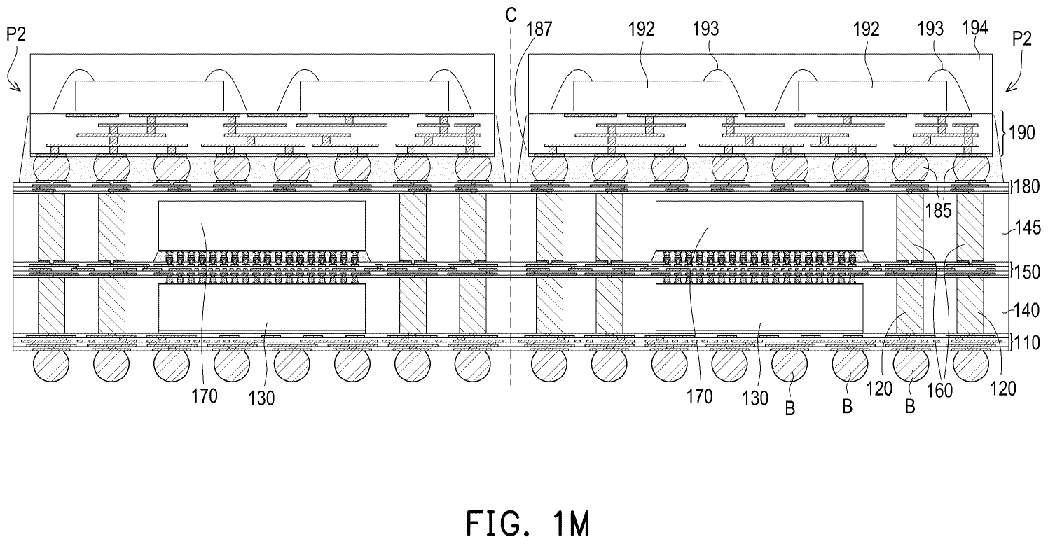

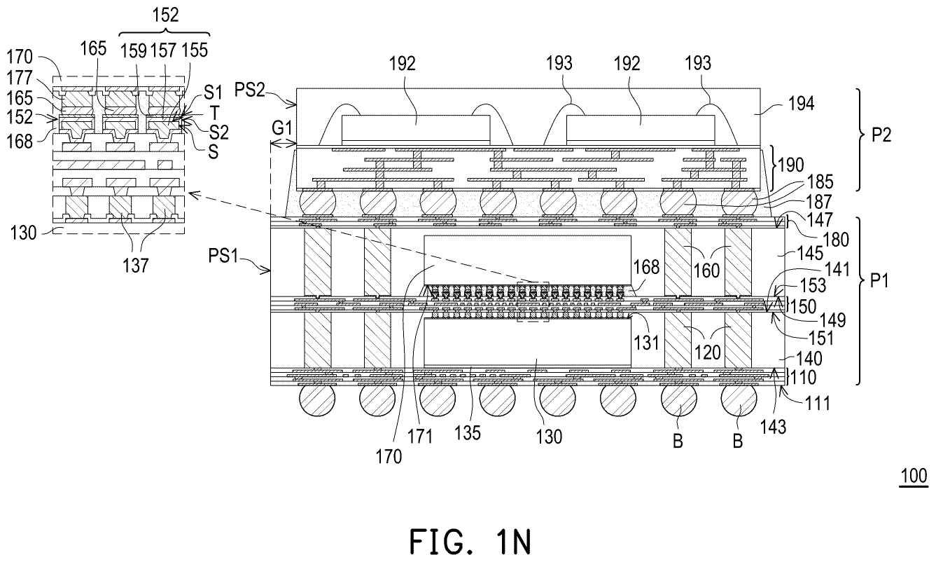

FIG. 1A to FIG. 1N are schematic cross-sectional views of a manufacturing method of a semiconductor package structure according to an embodiment of the disclosure. According to the manufacturing method of the semiconductor package structure of the embodiment, first, please refer to FIG. 1A. A carrier plate 10 and a first redistribution layer 110 formed on the carrier plate 10 are provided. In detail, first, the carrier plate 10 is provided, wherein the carrier plate 10 may be, for example, a glass substrate, a silicon substrate, or a metal substrate, but not limited thereto. In an embodiment, the material of the carrier plate 10 is not particularly limited, as long as the carrier plate 10 is suitable for carrying a film layer formed thereon or a component disposed thereon.

Next, please refer to FIG. 1A again. A release layer 20 is formed on the carrier plate 10, wherein the release layer 20 may directly cover a surface 11 of the carrier plate 10. In an embodiment, the release layer 20 may be, for example, formed through coating, but not limited thereto.

Next, please refer to FIG. 1A again. The first redistribution layer 110 is formed on the release layer 20, wherein the release layer 20 is located between the first redistribution layer 110 and the carrier plate 10. The first redistribution layer 110 may include an insulating layer 112 and a conductive layer 114. The conductive layer 114 may form a corresponding circuit, wherein the layout design of the circuit may be adjusted according to requirements and is not limited herein.

For example, in the circuit of the first redistribution layer 110, parts that are not connected in the drawing may be electrically connected by other unshown places and/or other conductive components. In the embodiment, the first redistribution layer 110 may be formed by a conventional semiconductor process (for example, a deposition process, a photolithography process, and/or an etching process, etc.), so there will be no elaboration. In an embodiment, the first redistribution layer 110 may be, for example, a fan-out redistribution layer, but not limited thereto.

Next, please refer to FIG. 1A again. Multiple first conductive elements 120 are formed on the first redistribution layer 110, wherein the first conductive elements 120 are electrically connected to the first redistribution layer 110. In an embodiment, the first conductive element 120 may be, for example, a columnar conductive element, but not limited thereto. In an embodiment, the first conductive element 120 may be formed by a conventional semiconductor process (for example, a photolithography process, a sputtering process, an electroplating process, and/or an etching process, etc.), but not limited thereto. In an embodiment, the material of the first conductive element 120 is, for example, copper, but not limited thereto.

Next, please refer to FIG. 1B. At least one first chip 130 (two first chips 130 are schematically shown) is disposed on the first redistribution layer 110, wherein an adhesion layer 135 is disposed on the first redistribution layer 110, and the first chip 130 is fixed on the first redistribution layer 110 through the adhesion layer 135. The first chip 130 has a first active surface 131 and a back surface 133 opposite to each other, wherein the first active surface 131 is a surface where a component area is located. The first chip 130 directly contacts the adhesion layer 135 with the back surface 133, and the first active surface 131 faces upward away from the first redistribution layer 110. In an embodiment, the first chip 130 may be, for example, an active integrated circuit (IC), but not limited thereto. In an embodiment, the adhesion layer 135 is, for example, a die-attach film (DAF), but not limited thereto.

Please refer to FIG. 1B again. Multiple third conductive elements 137 are formed on a wafer (not shown), and then the grind wafer is ground and singulated to form the first chip 130 and the third conductive element 137 located on the first active surface 131. In an embodiment, the third conductive element 137 may be, for example, a copper column or a copper bump, but not limited thereto. In an embodiment, the third conductive element 137 may be formed by a conventional semiconductor process (for example, a photolithography process, a sputtering process, an electroplating process, and/or an etching process, etc.), but not limited thereto.

Next, please refer to FIG. 1C. A first encapsulant 140 is formed on the first redistribution layer 110. The first encapsulant 140 encapsulates the first chip 130, the first conductive element 120, and the third conductive element 137, and exposes a first surface 121 of each first conductive element 120 and a surface 138 of each third conductive element 137. In an embodiment, the material of the first encapsulant 140 is, for example, an epoxy molding compound (EMC), wherein the first encapsulant 140 is, for example, formed by a molding process, but not limited thereto.

For example, a molding material may be formed on the first redistribution layer 110, and after curing the molding material, a planarization process may be performed to form the first encapsulant 140. After the planarization process, the first encapsulant 140 may expose the first surface 121 of the first conductive element 120 and the surface 138 of the third conductive element 137. In other words, a surface of the first encapsulant 140 away from the first redistribution layer 110 may be coplanar with the first surface 121 of the first conductive element 120 and the surface 138 of the third conductive element 137. During the planarization process, a part of the cured molding material and/or a part of the first conductive element 120 and/or a part of the third conductive element 137 may be slightly removed. In an embodiment, the planarization process is, for example, a grinding process.

Next, please refer to FIG. 1D. A second redistribution layer 150 is formed on the first surface 121 of each first conductive element 120, the surface 138 of the third conductive element 137, and the first encapsulant 140. The second redistribution layer 150 has a first side 151 and a second side 153 opposite to each other. The first chip 130 is electrically connected to the first side 151 of the second redistribution layer 150 through the third conductive element 137, and the first conductive element 120 is directly electrically connected to the first side 151 of the second redistribution layer 150.

In an embodiment, the second redistribution layer 150 may include an insulating layer 154 and a conductive layer 156. The conductive layer 156 may form a corresponding circuit, wherein the layout design of the circuit may be adjusted according to requirements and is not limited herein. For example, in the circuit of the second redistribution layer 150, parts that are not connected in the drawing may be electrically connected through other unshown places and/or other conductive components. In the embodiment, the second redistribution layer 150 may be formed by a conventional semiconductor process (for example, a deposition process, a photolithography process, and/or an etching process), so there will be no elaboration. In an embodiment, the second redistribution layer 150 may be, for example, a fan-out redistribution layer, but not limited thereto. In an embodiment, the second redistribution layer 150 may be, for example, a 5P5M redistribution layer (consisting of 5 insulating layers 154 plus 5 conductive layers 156), but not limited thereto.

Next, please refer to FIG. 1E. A seed layer 30 is formed on the second side 153 of the second redistribution layer 150, wherein the seed layer 30 is, for example, formed through a sputtering process in physical vapor deposition (PVD), and the seed layer 30 is, for example, a titanium/copper stacked layer, but not limited thereto. Next, a patterned photoresist layer 40 is formed on the seed layer 30. The patterned photoresist layer 40 has multiple first openings 42, and the first openings 42 respectively expose a first part 31 of the seed layer 30. Next, using the patterned photoresist layer 40 as an electroplating mask, each connecting pad 155 is electroplated on the first part 31 of the seed layer 30 exposed by each first opening 42, wherein each first opening 42 exposes a top surface T of each connecting pad 155. Here, each connecting pad 155 has the top surface T and a peripheral surface S connected to the top surface T, and the peripheral surface S of each connecting pad 155 directly contacts an inner wall of the corresponding first opening 42. In other words, there is no gap between the peripheral surface S of each connecting pad 155 and the inner wall of the corresponding first opening 42. In an embodiment, the material of the connecting pad 155 is, for example, copper, but not limited thereto.

Next, please refer to FIG. 1E and FIG. 1F at the same time. A part of the patterned photoresist layer 40 located around each connecting pad 155 is removed to form a photoresist layer 40′ having multiple second openings 44. Each second opening 44 exposes the top surface T and the peripheral surface S of each connecting pad 155 and a second part 33 of the seed layer 30. In other words, the peripheral surface S of each connecting pad 155 is spaced apart from an inner wall of the corresponding second opening 44.

In an embodiment, a method of removing the part of the patterned photoresist layer 40 located around each connecting pad 155 is, for example, an exposure procedure and a development procedure, which means that the photoresist layer 40′ having the larger second opening 44 is formed through re-exposure and re-development. In another embodiment, the method of removing the part of the patterned photoresist layer 40 around each connecting pad 155 may also be, for example, an over development procedure, which means that the photoresist layer 40′ having the larger second opening 44 is formed through over development. In another embodiment, the method of removing the part of the patterned photoresist layer 40 around each connecting pad 155 may also be, for example, a plasma dry etching procedure, which means that the photoresist layer 40′ having the larger second opening 44 is formed through plasma dry etching.

Next, please refer to FIG. 1F and FIG. 1G at the same time. Using the photoresist layer 40′ as an electroplating mask, a nickel layer 157 is electroplated on the top surface T and the peripheral surface S and the top surface T of each connecting pad 155 and the second part 33 of the seed layer 30 exposed by each second opening 44. In an embodiment, the thickness of the nickel layer 157 on the peripheral surface S may be less than or equal to the thickness on the top surface T, and the thickness of the electroplated nickel layer may be adjusted according to requirements. Then, the photoresist layer 40′ is used as an electroplating mask again, and a gold layer 159 is electroplated on the nickel layer 157. At this time, the gold layer 159 is only formed on the nickel layer 157 located on the top surface T of the connecting pad 155. In other words, the gold layer 159 does not encapsulate a peripheral surface of the nickel layer 157, and the gold layer 159 and the nickel layer 157 are not conformal. Afterwards, the photoresist layer 40′ is removed to expose the seed layer 30 below the photoresist layer 40′. Next, a patterned photoresist layer (not shown) is formed on the seed layer 30, wherein the patterned photoresist layer exposes a third part 35 of the seed layer 30. Next, using the patterned photoresist layer as an electroplating mask, multiple second conductive elements 160 are electroplated on the third part 35 of the seed layer 30. Finally, the patterned photoresist layer is removed and the seed layer 30 exposed below the patterned photoresist layer is removed through etching to expose the second side 153 of the second redistribution layer 150. So far, multiple chip connectors 152 and the second conductive elements 160 are formed on the second side 153 of the second redistribution layer 150.

Here, each chip connector 152 includes the connecting pad 155, the nickel layer 157, and the gold layer 159. The connecting pad 155 has the top surface T and the peripheral surface S connected to the top surface T. The nickel layer 157 covers the top surface T and the peripheral surface S of the connecting pad 155, and the gold layer 159 directly covers the nickel layer 157 located on the top surface T of the connecting pad 155. In other words, the top surface T and the peripheral surface S of the connecting pad 155 are directly covered by the nickel layer 157, and the gold layer 159 is limited to being located on the nickel layer 157 on the top surface T. In addition, each chip connector 152 and each second conductive element 160 are respectively electrically connected to the second redistribution layer 150.

Since the chip connector 152 and the second conductive element 160 of the embodiment may be formed using the same seed layer 30, costs can be saved and the manufacturing process can be simplified.

Next, please refer to FIG. 1H. Multiple solders 165 are disposed on at least one second chip 170 (two second chips 170 are schematically shown), wherein the second chip 170 is disposed on the chip connector 152 through the solder 165 and is electrically connected to the second side 153 of the second redistribution layer 150. In an embodiment, multiple fourth conductive elements 177 are formed on a second active surface 171 of the second chip 170, wherein the solders 165 are respectively located between the fourth conductive element 177 and the chip connector 152. In other words, the second chip 170 is disposed on the second redistribution layer 150 using flip chip bonding. In an embodiment, the second chip 170 may be, for example, a system-on-chip (SOC), but not limited thereto. In an embodiment, the fourth conductive element 177 may be, for example, a copper pillar or a copper bump, but not limited thereto.

Nickel is often used as a barrier metal for solder bonding due to advantages such as alloy inertness and high melting point. Since the nickel layer 157 may reduce the rate of generating intermetallic compounds (IMC) by reaction between copper and tin during high temperature reflow, the rate of IMC formation between copper and tin atoms by diffusion can be reduced during the reflow process and reliability testing. Furthermore, there is the nickel layer 157 and the gold layer 159 between the solder 165 and the connecting pad 155 of the chip connector 152, wherein the nickel layer 157 covers the top surface T and the peripheral surface S of the connecting pad 155, and the gold layer 159 covers the nickel layer 157 located on the top surface T of the connecting pad 155. Therefore, an interacting region between the solder 165 and the gold layer 159 may be limited to prevent the solder 165 from overflowing to a side surface of the chip connector 152 in a reflow molten state that causes insufficient solder 165 directly above the gold layer 159 (in a direction perpendicular to the top surface T of the connecting pad 155) and forms a structurally poor solder joint bonding state. At the same time, the nickel layer 157 may prevent the peripheral surface S of the connecting pad 155 from being laterally eroded, thereby achieving improved structural reliability. In addition, the geometrical structure design of the chip connector 152 may also reduce the risk of solder joint breakage after high temperature storage (HTS). In other words, the design of the chip connector 152 may be suitable for multiple high temperature procedures. In an embodiment, due to the geometrical structure design of the chip connector 152, the spacing design including the chip connector 152, the solder 165, and the fourth conductive element 177 may be further reduced.

Next, please refer to FIG. 1H again. In order to effectively protect the electrical connection between the second chip 170 and the second redistribution layer 150, an underfill 168 may be formed to be filled between the second chip 170 and the second side 153 of the second redistribution layer 150, and the underfill 168 may encapsulate the solder 165 and the chip connector 152. In an embodiment, the material of the underfill 168 may be, for example, resin, epoxy, or a molding compound, but not limited thereto. In an embodiment, the underfill 168 may also be replaced by a non-conductive film (NCF), which still falls within the protection scope of the disclosure.

Next, please refer to FIG. 1I. A second encapsulant 145 is formed on the second redistribution layer 150. The second encapsulant 145 encapsulates the second chip 170, the second conductive element 160, and the underfill 168 and exposes a second surface 161 of each second conductive element 160. In an embodiment, the material of the second encapsulant 145 is, for example, an epoxy molding compound (EMC), wherein the second encapsulant 145 is, for example, formed by a molding process, but not limited thereto.

For example, a sealing material may be formed on the second redistribution layer 150, and after curing the sealing material, a planarization process may be performed to form the second encapsulant 145. After the planarization process, the second encapsulant 145 may expose the second surface 161 of the second conductive element 160. In other words, a surface of the second encapsulant 145 away from the second redistribution layer 150 may be coplanar with the second surface 161 of the second conductive element 160. During the planarization process, a part of the cured molding material and/or a part of the second conductive element 160 may be slightly removed. In an embodiment, the planarization process is, for example, a grinding process. In an embodiment, a thicker second chip 170 may also be disposed first to improve solder joint performance because the thicker second chip 170 may improve the warpage of the chip, and then the thickness of the second chip 170 may be removed to the target thickness at the same time when a portion of the encapsulant material is removed by the planarization process. In other word, the back surface of the second chip 170 may or may not be exposed to the second encapsulant 145 depending on the requirements.

Next, please refer to FIG. 1J. A third redistribution layer 180 is formed on the second surface 161 of each second conductive element 160 and the second encapsulant 145. The third redistribution layer 180 is directly electrically connected to the second conductive element 160. In an embodiment, the third redistribution layer 180 may include an insulating layer 182 and a conductive layer 184. The conductive layer 184 may form a corresponding circuit, wherein the layout design of the circuit may be adjusted according to requirements and is not limited herein.

For example, in the circuit of the third redistribution layer 180, parts that are not connected in the drawing may be electrically connected through other places not shown and/or other conductive components. In the embodiment, the third redistribution layer 180 may be formed by a conventional semiconductor process (for example, a deposition process, a photolithography process, and/or an etching process), so there will be no elaboration. In an embodiment, the third redistribution layer 180 may be, for example, a fan-out redistribution layer, but not limited thereto.

Next, please refer to FIG. 1J and FIG. 1K at the same time. The carrier plate 10 is removed by peeling off the release layer 20 to expose the first redistribution layer 110, wherein the first redistribution layer 110, the second redistribution layer 150, the third redistribution layer 180, the first chip 130, the second chip 170, the first conductive element 120, the second conductive element 160, the first encapsulant 140, the second encapsulant 145, and the solder 165 define a first package P1. Here, the first package P1 has, for example, a fan-out package structure sequentially stacked from bottom to top and having two layers of encapsulants.

Next, please refer to FIG. 1L. Multiple solder balls B are formed on the first package P1 and are located on a surface 111 of the first redistribution layer 110 away from the first chip 130. The solder ball B is electrically connected to the first redistribution layer 110 of the first package P1.

After that, please refer to FIG. 1M. At least one second package P2 (two second packages P2 are schematically shown) is disposed on the third redistribution layer 180 of the first package P1 and is electrically connected to the first package P1 through multiple connectors 185.

In an embodiment, the second package P2 includes a substrate 190, at least one third chip 192 (two third chips 192 are schematically shown) and a third encapsulant 194. The third chip 192 is disposed on the substrate 190 and is, for example, electrically connected to the substrate 190 through a wire 193. The third encapsulant 194 seals the third chip 192. The substrate 190 is located between the third chip 192 and the first package P1. In an embodiment, the third chip 192 may be, for example, an active chip and/or a passive chip, but not limited thereto. The connector 185 is disposed between the first package P1 and the second package P2, wherein the connector 185 is, for example, a solder ball, but not limited thereto. In addition, in order to effectively protect the electrical connection relationship between the first package P1 and the second package P2, an underfill 187 may also be filled between the first package P1 and the second package P2 and may encapsulate the connector 185.

In an embodiment, the second package P2 may also have, for example, an embedded multi chip package (eMCP) structure, a wafer level chip scale package structure, or other appropriate package structures, which are not limited herein.

Finally, please refer to FIG. 1M and FIG. 1N at the same time. A singulation procedure is executed along a cutting line C to cut the first package P1 to form multiple semiconductor package structures 100 as shown in FIG. 1N. So far, the manufacture of the semiconductor package structure 100 is completed.

Structurally, please refer to FIG. 1N again. The semiconductor package structure 100 includes the first package P1 and the second package P2. The first package P1 includes the first redistribution layer 110, the second redistribution layer 150, the third redistribution layer 180, the first chip 130, the second chip 170, the first conductive element 120, the second conductive element 160, the first encapsulant 140, the second encapsulant 145, and the solder 165. The second redistribution layer 150 is located between the first redistribution layer 110 and the third redistribution layer 180. The second redistribution layer 150 has the first side 151 and the second side 153 opposite each other and includes the chip connector 152 located on the second side 153. Each chip connector 152 includes the connecting pad 155, the nickel layer 157, and the gold layer 159. The connecting pad 155 has the top surface T and the peripheral surface S connected to the top surface T. The nickel layer 157 covers the top surface T and the peripheral surface S of the connecting pad 155, and the gold layer 159 covers the nickel layer 157 located on the top surface T of the connecting pad 155. The first chip 130 is disposed on the first redistribution layer 110 and is electrically connected to the first side 151 of the second redistribution layer 150. The second chip 170 is disposed on the chip connector 152 through the solder 165 and is electrically connected to the second side 153 of the second redistribution layer 150. The first conductive element 120 is electrically connected to the first redistribution layer 110 and the second redistribution layer 150. The second conductive element 160 is electrically connected to the second redistribution layer 150 and the third redistribution layer 180. The first encapsulant 140 encapsulates the first chip 130 and the first conductive element 120. The second encapsulant 145 encapsulates the second chip 170 and the second conductive element 160. The second package P2 is disposed on the third redistribution layer 180 of the first package P1 and is electrically connected to the first package P1.

Furthermore, in the embodiment, the first redistribution layer 110, the second redistribution layer 150, and the third redistribution layer 180 may respectively be, for example, a fan-out redistribution layer, but not limited thereto. The first conductive element 120 is disposed on the first redistribution layer 110 and is connected to the first side 151 of the second redistribution layer 150. The first chip 130 is located between the first conductive elements 120. The first encapsulant 140 has an upper surface 141 and a lower surface 143 opposite to each other. The upper surface 141 covers the first side 151 of the second redistribution layer 150, and the lower surface 143 covers the first redistribution layer 110. The second conductive element 160 is disposed on the second side 153 of the second redistribution layer 150 and is connected to the third redistribution layer 180. The second chip 170 is located between the second conductive elements 160. The second encapsulant 145 has an upper surface 147 and a lower surface 149 opposite to each other. The upper surface 147 covers the third redistribution layer 180, and the lower surface 149 covers the second side 153 of the second redistribution layer 150.

In an embodiment, an orthographic projection of each first conductive element 120 on the second redistribution layer 150 is aligned with an orthographic projection of each second conductive element 160 on the second redistribution layer 150. In another embodiment not shown, the orthographic projection of each first conductive element 120 on the second redistribution layer 150 may also be misaligned with the orthographic projection of each second conductive element 160 on the second redistribution layer 150.

Furthermore, in the embodiment, the semiconductor package structure 100 further includes the adhesion layer 135 disposed on the first redistribution layer 110, wherein the first chip 130 is fixed on the first redistribution layer 110 through the adhesion layer 135. The semiconductor package structure 100 of the embodiment also includes the third conductive element 137 and the fourth conductive element 177. The third conductive element 137 is disposed on the first active surface 131 of the first chip 130, wherein the first chip 130 is electrically connected to the second redistribution layer 150 through the third conductive element 137. The fourth conductive element 177 is disposed on the second active surface 171 of the second chip 170, wherein the solder 165 is located between the fourth conductive element 177 and the chip connector 152. The first active surface 131 of the first chip 130 and the second active surface 171 of the second chip 170 are stacked face to face and electrically connected through the redistribution layer 150. In an embodiment, the position of the third conductive element 137 may correspond to the position of the fourth conductive element 177 one-to-one, so that the shortest electrical transmission path may be provided between the first chip 130 and the second chip 170.

In particular, in the embodiment, the nickel layer 157 of the chip connector 152 covers the top surface T and the peripheral surface S of the connecting pad 155, that is, directly encapsulates the peripheral surface S of the connecting pad 155, and the gold layer 159 covers the nickel layer 157 located on the top surface T of the connecting pad 155, that is, the gold layer 159 is limited to the top surface T. In other words, a first peripheral edge S1 of the gold layer 159 of each chip connector 152 is flush with a second peripheral edge S2 of the nickel layer 157, and the peripheral surface S of the connecting pad 155 is retracted relative to the first peripheral edge S1. Through the geometrical structure design of the chip connector 152, the interacting region between the solder 165 and the gold layer 159 may be limited to prevent the solder 165 from overflowing to the side surface of the chip connector 152 in the reflow molten state that causes insufficient solder 165 directly above the gold layer 159 (in the direction perpendicular to the top surface T of the connecting pad 155) and forms a structurally poor solder joint bonding state, and the nickel layer 157 encapsulating the peripheral surface S of the connecting pad 155 may prevent the peripheral surface S of the connecting pad 155 from being laterally eroded, thereby achieving improved structural reliability.

Furthermore, in order to effectively protect the electrical connection relationship between the second chip 170 and the second redistribution layer 150, the semiconductor package structure 100 may also include the underfill 168 filled between the second chip 170 and the second side 153 of the second redistribution layer 150 and encapsulating the solder 165 and the chip connector 152. In an embodiment, an orthographic projection of the second chip 170 on the second redistribution layer 150 may overlap with an orthographic projection of the first chip 130 on the second redistribution layer 150, but not limited thereto. In addition, the semiconductor package structure 100 also includes the solder ball B disposed on the first package P1 and located on the surface 111 of the first redistribution layer 110 away from the first chip 130. The solder ball B is electrically connected to the first redistribution layer 110 of the first package P1, wherein the semiconductor package structure 100 may be electrically connected to an external circuit (for example, a circuit board, etc.) through the solder ball B.

Please refer to FIG. 1N again. The semiconductor package structure 100 of the embodiment also includes multiple connectors 185 disposed between the first package P1 and the second package P2. The second package P2 is electrically connected to the first package P1 through the connector 185. Furthermore, the second package P2 of the embodiment includes, for example, the substrate 190, the third chip 192, and the third encapsulant 194. The third chip 192 is disposed on the substrate 190 and is, for example, electrically connected to the substrate 190 through the wire 193. The third encapsulant 194 seals the third chip 192. The substrate 190 is located between the third chip 192 and the first package P1. In order to effectively protect the electrical connection relationship between the first package P1 and the second package P2, the semiconductor package structure 100 of the embodiment may also include the underfill 187 filled between the first package P1 and the second package P2 and encapsulating the connector 185. In an embodiment, a first peripheral edge PS1 of the first package P1 may protrude a spacing G1 relative to a second peripheral edge PS2 of the second package P2, but not limited thereto.

The embodiment does not limit the structural type of the second package P2. In an embodiment, the second package P2 may also have, for example, an embedded multi chip package (eMCP) structure, a wafer level chip scale package structure, or other appropriate package structures.

As shown in FIG. 1N, in the first package P1, multiple chips (for example, the first chip 130 and the second chip 170) may be disposed in multiple redistribution layers (for example, the first redistribution layer 110, the second redistribution layer 150, and the third redistribution layer 180) to have more space to integrate multi-functional chips, such as processors, power management IC (PMIC), integrated passive devices (IPD), integrated voltage regulators (IVR), memories, passive components, or other appropriate chips, which are not limited herein. 3D stacking of multiple chips (for example, the first chip 130 and the second chip 170) face-to-face (i.e., active surfaces facing each other) on the same redistribution layer not only helps to reduce package size, but also allows for shortest possible transmission path between the multiple chips. Compared with package on package (POP) in the prior art, the first chip 130 and the second chip 170 of the embodiment may share the middle second redistribution layer 150, that is, the number of redistribution layers is lower, which can effectively reduce package thickness, that is, reduce the overall height in the Z direction. In other words, besides the second redistribution layer 150 shared between the first chip 130 and the second chip 170 for Z-height reduction, another key point is chip level integration vertically by micro-bumps can significantly reduce Z-height in comparison to bulk solder balls adopted in conventional PoP structure. In addition, for double-sided molding fan-out packaging between chips, an additional top-side molding material (that is, the second encapsulant 145) and the thickness may be adjusted to obtain a more balanced structure, thereby controlling the first package P1 warpage, which can improve the stacking yield of fan-out packaging. In other words, the first package P1 warpage can be well controlled to fit the second package P2 warpage behavior and obtain better stacking yield performance. In addition, the above structure may be applied to a high-end product, which can provide more design flexibility and freedom.

In summary, in the semiconductor package structure of the disclosure, the chip connector includes the connecting pad, the nickel layer, and the gold layer, wherein the nickel layer covers the top surface and the peripheral surface of the connecting pad, and the gold layer covers the nickel layer located on the top surface of the connecting pad. Through the geometrical structure design of the chip connector, the interacting region between the solder and the gold layer may be limited to prevent the solder from overflowing to the side surface of the chip connector in the reflow molten state that causes insufficient solder directly above the gold layer (in the direction perpendicular to the top surface of the connecting pad) and forms a structurally poor solder joint bonding state, and the nickel layer encapsulating the peripheral surface of the connecting pad may prevent the peripheral surface of the connecting pad from being laterally eroded, thereby achieving improved structural reliability.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A semiconductor package structure, comprising:
a first package, comprising a first redistribution layer, a second redistribution layer, a third redistribution layer, at least one first chip, at least one second chip, a plurality of first conductive elements, a plurality of second conductive elements, a first encapsulant, a second encapsulant, and a plurality of solders, wherein the second redistribution layer is located between the first redistribution layer and the third redistribution layer, the second redistribution layer has a first side and a second side opposite to each other and comprises a plurality of chip connectors located on the second side, each of the chip connectors comprises a connecting pad, a nickel layer, and a gold layer, the connecting pad has a top surface and a peripheral surface connected to the top surface, the nickel layer covers the top surface and the peripheral surface of the connecting pad, and the gold layer covers the nickel layer located on the top surface of the connecting pad, the at least one first chip is disposed on the first redistribution layer and is electrically connected to the first side of the second redistribution layer, the at least one second chip is disposed on the chip connectors through the solders and is electrically connected to the second side of the second redistribution layer, the first conductive elements are electrically connected to the first redistribution layer and the second redistribution layer, the second conductive elements are electrically connected to the second redistribution layer and the third redistribution layer, the first encapsulant encapsulates the at least one first chip and the first conductive elements, and the second encapsulant encapsulates the at least one second chip and the second conductive elements; and
a second package, disposed on the third redistribution layer of the first package and electrically connected to the first package.

2. The semiconductor package structure according to claim 1, further comprising:
a plurality of third conductive elements, disposed on at least one first active surface of the at least one first chip, wherein the at least one first chip is electrically connected to the second redistribution layer through the third conductive elements; and
a plurality of fourth conductive elements, disposed on at least one second active surface of the at least one second chip, wherein the solders are respectively located between the fourth conductive elements and the chip connectors.

3. The semiconductor package structure according to claim 1, wherein the first conductive elements are disposed on the first redistribution layer and are connected to the first side of the second redistribution layer, the at least one first chip is located between the first conductive elements, the first encapsulant has an upper surface and a lower surface opposite to each other, the upper surface covers the first side of the second redistribution layer, and the lower surface covers the first redistribution layer.

4. The semiconductor package structure according to claim 1, wherein the second conductive elements are disposed on the second side of the second redistribution layer and are connected to the third redistribution layer, the at least one second chip is located between the second conductive elements, the second encapsulant has an upper surface and a lower surface opposite to each other, the upper surface covers the third redistribution layer, and the lower surface covers the second side of the second redistribution layer.

5. The semiconductor package structure according to claim 1, wherein an orthographic projection of each of the first conductive elements on the second redistribution layer is aligned or misaligned with an orthographic projection of each of the second conductive elements on the second redistribution layer.

6. The semiconductor package structure according to claim 1, further comprising:
a plurality of solder balls, disposed on the first package and located on a surface of the first redistribution layer away from the at least one first chip, wherein the solder balls are electrically connected to the first redistribution layer of the first package.

7. The semiconductor package structure according to claim 1, wherein the second package comprises a substrate, at least one third chip, and a third encapsulant, the at least one third chip is disposed on the substrate and is electrically connected to the substrate, the third encapsulant seals the at least one third chip, and the substrate is located between the at least one third chip and the first package.

8. The semiconductor package structure according to claim 1, further comprising:
a plurality of connectors, disposed between the first package and the second package, wherein the second package is electrically connected to the first package through the connectors.

9. The semiconductor package structure according to claim 8, further comprising:
an underfill, filled between the first package and the second package and encapsulating the connectors.

10. The semiconductor package structure according to claim 1, further comprising:
an underfill, filled between the at least one second chip and the second side of the second redistribution layer and encapsulating the solders and the chip connectors.

11. The semiconductor package structure according to claim 1, further comprising:
an adhesion layer, disposed on the first redistribution layer, wherein the at least one first chip is fixed on the first redistribution layer through the adhesion layer.

12. The semiconductor package structure according to claim 1, wherein an orthographic projection of the at least one second chip on the second redistribution layer overlaps with an orthographic projection of the at least one first chip on the second redistribution layer.

13. The semiconductor package structure according to claim 1, wherein a first peripheral edge of the first package protrudes a spacing relative to a second peripheral edge of the second package.

14. The semiconductor package structure according to claim 1, wherein the first redistribution layer, the second redistribution layer, and the third redistribution layer respectively comprise a fan-out redistribution layer.

15. The semiconductor package structure according to claim 1, wherein a first peripheral edge of the gold layer of each of the chip connectors is flush with a second peripheral edge of the nickel layer, and the peripheral surface of the connecting pad is retracted relative to the first peripheral edge.

16. A manufacturing method of a semiconductor package structure, comprising:
providing a carrier plate and a first redistribution layer formed on the carrier plate;
forming a plurality of first conductive elements on the first redistribution layer and electrically connected to the first redistribution layer;
disposing at least one first chip on the first redistribution layer;
forming a first encapsulant on the first redistribution layer, wherein the first encapsulant encapsulates the at least one first chip and the first conductive elements and exposes a first surface of each of the first conductive elements;
forming a second redistribution layer on the first surface of each of the first conductive elements and the first encapsulant, wherein the second redistribution layer has a first side and a second side opposite to each other, the at least one first chip and the first conductive elements are electrically connected to the first side of the second redistribution layer;
forming a plurality of chip connectors on the second side of the second redistribution layer, wherein each of the chip connectors comprises a connecting pad, a nickel layer, and a gold layer, the connecting pad has a top surface and a peripheral surface connected to the top surface, the nickel layer covers the top surface and the peripheral surface of the connecting pad, and the gold layer covers the nickel layer located on the top surface of the connecting pad;
forming a plurality of second conductive elements on the second side of the second redistribution layer and electrically connected to the second redistribution layer;
forming a plurality of solders on at least one second chip, wherein the at least one second chip is disposed on the chip connectors through the solders and is electrically connected to the second side of the second redistribution layer;
forming a second encapsulant on the second redistribution layer, wherein the second encapsulant encapsulates the at least one second chip and the second conductive elements and exposes a second surface of each of the second conductive elements;
forming a third redistribution layer on the second surface of each of the second conductive elements and the second encapsulant, wherein the third redistribution layer is electrically connected to the second conductive elements;
removing the carrier plate to expose the first redistribution layer, wherein the first redistribution layer, the second redistribution layer, the third redistribution layer, the at least one first chip, the at least one second chip, the first conductive elements, the second conductive elements, the first encapsulant, the second encapsulant, and the solders define a first package; and
disposing at least one second package on the third redistribution layer of the first package and electrically connected to the first package.

17. The manufacturing method of the semiconductor package structure according to claim 16, wherein the step of forming the chip connectors on the second side of the second redistribution layer comprises:
forming a seed layer on the second side of the second redistribution layer;
forming a patterned photoresist layer on the seed layer, wherein the patterned photoresist layer has a plurality of first openings, and the first openings respectively expose a first part of the seed layer;
electroplating each of the connecting pads on the first part of the seed layer exposed by each of the first openings using the patterned photoresist layer as an electroplating mask, wherein each of the first openings exposes the top surface of each of the connecting pads;
removing a part of the patterned photoresist layer located around each of the connecting pads to form a photoresist layer having a plurality of second openings, wherein each of the second openings exposes the top surface and the peripheral surface of each of the connecting pads and a second part of the seed layer;
electroplating the nickel layer on the top surface and the peripheral surface of each of the connecting pads and the second part of the seed layer exposed by each of the second openings using the photoresist layer as an electroplating mask;
electroplating the gold layer on the nickel layer using the photoresist layer as an electroplating mask; and
removing the photoresist layer and the seed layer below the photoresist layer.

18. The manufacturing method of the semiconductor package structure according to claim 17, wherein the step of forming the second conductive elements on the second side of the second redistribution layer comprises:
electroplating the second conductive elements on a third part of the seed layer when removing the photoresist layer to expose the seed layer below the photoresist layer.

19. The manufacturing method of the semiconductor package structure according to claim 17, wherein a method of removing the part of the patterned photoresist layer located around each of the connecting pads comprises an exposure procedure and a development procedure, an over development procedure, or a plasma dry etching procedure.

20. The manufacturing method of the semiconductor package structure according to claim 16, wherein a singulation procedure is executed after disposing the at least one second package on the third redistribution layer of the first package.
